(19) United States
(12) Patent Application Publication
(10) Pub. No.: US 2022/0302885 A1
(43) Pub. Date: Sep. 22, 2022

(54) HIGH-FREQUENCY AMPLIFIER CIRCUIT

(71) Applicants: Kabushiki Kaisha Toshiba, Tokyo (JP); Toshiba Electronic Devices & Storage Corporation, Tokyo (JP)

(72) Inventors: Toshiki SESHITA, Kawasaki Kanagawa (JP); Yasuhiko KURIYAMA, Yokohama Kanagawa (JP)

(21) Appl. No.: 17/472,289

(22) Filed: Sep. 10, 2021

(30) Foreign Application Priority Data
Mar. 19, 2021 (JP) 2020-045472

(51) Int. Cl. H03F 3/195; H03F 1/22; H03F 3/72; H03F 1/56; H03F 1/26

(52) U.S. Cl. CPC H03F 3/195; H03F 1/223; H03F 3/72; H03F 1/565; H03F 1/26; H03F 2200/294; H03F 2200/451; H03F 2203/7206

(57) ABSTRACT

According to one embodiment, a high frequency amplifier circuit includes a first transistor including a gate to which an input signal is input; a second transistor including a gate grounded, and a source coupled to a drain of the first transistor; a first switch coupled between a first output terminal and a first node located between the drain of the second transistor and an inductor; a third transistor including a gate to which the input signal is input; a fourth transistor including a gate that is grounded, and a source coupled to a drain of the third transistor; a second switch coupled between a second output terminal and a second node located between the drain of the fourth transistor and an inductor; and a third switch coupled between the first node and the second node.

### CROSS-REFERENCE TO RELATED APPLICATIONS

This application is based upon and claims the benefit of priority from Japanese Patent Application No. 2021-045472, filed Mar. 19, 2021, the entire contents of which are incorporated herein by reference.

### FIELD

Embodiments described herein relate generally to a high-frequency amplifier circuit.

### BACKGROUND

A high-frequency low-noise amplifier (LNA) used for a wireless device, etc. has been manufactured using a SiGe bipolar process. In recent years, however, such manufacturing has been replaced by manufacturing that uses a CMOS process for a silicon on insulator (SOI) substrate. This is because a highly functional high-frequency low-noise amplifier can be implemented by integrating a high-frequency switching field-effect transistor into a high-frequency low-noise amplifier.

In recent years, carrier aggregation (hereinafter also abbreviated as “CA”) has been introduced to enhance the speed of wireless communications. Modes of CA include intraband CA. In intraband CA, an output of an LNA needs to be split into two. That is, to implement an LNA compatible with the intraband CA, a split output mode as well as a single output mode is required. In the split output mode, the isolation between output ports is required to be, for example, equal to or higher than 25 dB; however, it is not easy to achieve such a high level of isolation.

### BRIEF DESCRIPTION OF THE DRAWINGS

FIG. 1 is a block diagram showing a configuration of a wireless device including a high-frequency amplifier circuit according to an embodiment.

FIG. 2 is a circuit diagram showing a configuration of the high-frequency amplifier circuit according to the embodiment.

FIG. 3 is a circuit diagram showing an on state and an off state in each of the switches according to the embodiment.

FIGS. 4-6 are schematic diagrams each showing an output switch circuit in the high-frequency amplifier circuit according to the embodiment.

FIG. 7 shows a state of each switch in a single output mode and a split output mode according to the embodiment.

FIG. 8 is a diagram showing an operation of a noise reduction circuit in the high-frequency amplifier circuit according to the embodiment.

FIG. 9 is a diagram showing an operation of an output isolation improving circuit in the high-frequency amplifier circuit according to the embodiment.

FIG. 10 shows a relationship of magnetic coupling of the output isolation improving circuit of the high-frequency amplifier circuit according to the embodiment.

FIG. 11 is a schematic diagram of a layout of the high-frequency amplifier circuit according to the embodiment.

FIG. 12 is a schematic diagram showing winding directions of inductors in FIG. 11.

FIG. 13 is a schematic diagram showing another example of winding directions of inductors in FIG. 11.

FIG. 14 is a diagram showing S-parameters of the high-frequency amplifier circuit in the single output mode according to the embodiment.

FIG. 15 is a diagram showing a noise figure of the high-frequency amplifier circuit in the single output mode according to the embodiment.

FIG. 16 is a diagram showing S-parameters of the high-frequency amplifier circuit in the split output mode according to the embodiment.

FIG. 17 is a diagram showing a noise figure of the high-frequency amplifier circuit in the split output mode according to the embodiment.

FIG. 18 is a circuit diagram showing a configuration of a high-frequency amplifier circuit according to a comparative example.

FIG. 19 is a schematic diagram showing winding directions of inductors in FIG. 18.

FIG. 20 is a diagram showing S-parameters in a single output mode according to the comparative example.

FIG. 21 is a diagram showing S-parameters in a split output mode according to the comparative example.

FIG. 22 is a diagram showing values of various characteristics according to the embodiment and the comparative example.

### DETAILED DESCRIPTION

In general, according to one embodiment, a high frequency amplifier circuit includes a first transistor including a gate to which an input signal is input; a first inductor coupled between a source of the first transistor and a reference voltage terminal; a second transistor including a gate that is grounded in an alternating-current manner, and a source coupled to a drain of the first transistor; a second inductor coupled between a drain of the second transistor and a power-supply voltage terminal; a first switch coupled between a first output terminal and a first node located between the drain of the second transistor and the second inductor; a third transistor including a gate to which the input signal is input; a third inductor coupled between a source of the third transistor and the reference voltage terminal; a fourth transistor including a gate that is grounded in the alternating-current manner, and a source coupled to a drain of the third transistor; a fourth inductor coupled between a drain of the fourth transistor and the power-supply voltage terminal; a second switch coupled between a second output terminal and a second node located between the drain of the fourth transistor and the fourth inductor; and a third switch coupled between the first node and the second node.

Hereinafter, embodiments will be described with reference to the accompanying drawings. In the description that follows, components having the same function and configuration will be assigned a common reference numeral. The embodiments to be described below are shown as an example of a device or a method for embodying the technical idea of the embodiments, and are not intended to limit the material, shape, structure, arrangement, etc. of components to those described below.

### 1. Embodiment

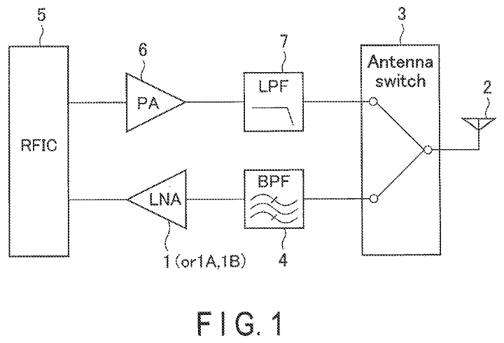

A high-frequency low-noise amplifier (hereinafter referred to as “high-frequency amplifier circuit”) is used in, for example, a wireless device such as a portable telephone and a smartphone. FIG. 1 is a block diagram showing a configuration of a wireless device including the high-frequency amplifier circuit according to an embodiment.

As shown in FIG. 1, the wireless device includes a high-frequency amplifier circuit 1, an antenna 2, an antenna switch 3, a band-pass filter (BPF) 4, a Radio Frequency Integrated Circuit (RFIC) 5, a power amplifier (PA) 6, and a low-pass filter (LPF) 7.

The antenna 2 transmits or receives a high-frequency signal. The antenna switch 3 is a switch that switches between transmission and reception of the high-frequency signal. FIG. 1 shows an example in which each of the transmitting side and the receiving side includes a single system; however, each of the transmitting side and the receiving side may include a plurality of systems that transmit and receive signals of a plurality of frequency bands.

The band-pass filter 4 passes signals of a predetermined frequency band, and cuts off signals of other frequency bands. The high-frequency amplifier circuit 1 of the present embodiment amplifies the signal that has passed through the band-pass filter 4, and outputs the amplified signal to the RFIC 5.

The RFIC 5 processes the signal received from the high-frequency amplifier circuit 1, and outputs a digital signal that is, for example, ultimately reproduced as character information, an image, sound, or the like. The RFIC 5 outputs a predetermined signal to the power amplifier 6.

The power amplifier 6 amplifies the signal output from the RFIC 5, and outputs the amplified signal to the low-pass filter 7. Of the signals output from the power amplifier 6, the low-pass filter 7 interrupts signals of a frequency higher than a predetermined frequency, and passes signals of a frequency lower than the predetermined frequency.

The antenna switch 3 and the high-frequency amplifier circuit 1 shown in FIG. 1 can be arranged on the same SOI substrate, and integrated into a single chip. By integrating the antenna switch 3 and the high-frequency amplifier circuit 1 into a single chip on an SOI substrate, it is possible to reduce the transmission loss of high-frequency signals. Through the single-chip integration, it is also possible to reduce the power consumption and the size of the high-frequency amplifier circuit 1.

1. 1 Circuit Configuration of High-Frequency Amplifier Circuit 1

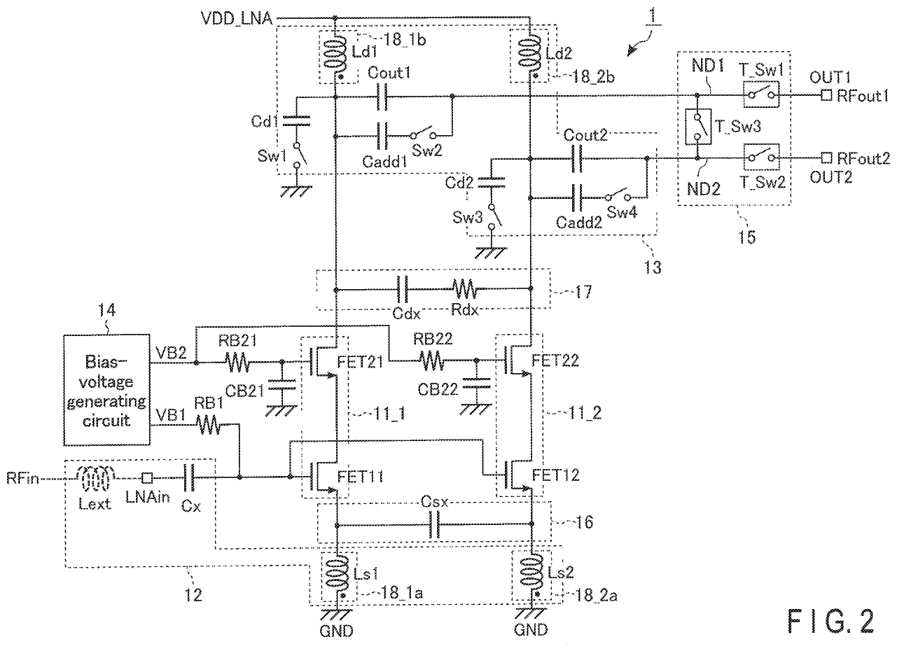

A circuit configuration of the high-frequency amplifier circuit 1 according to the embodiment will be described. FIG. 2 is a circuit diagram showing a configuration of the high-frequency amplifier circuit 1 according to the embodiment. The high-frequency amplifier circuit 1 includes cascade-coupled amplifier circuits 11_1 and 11_2, an input matching circuit 12, an output matching circuit 13, a bias-voltage generating circuit 14, an output switch circuit 15, a noise reduction circuit 16, output isolation improving circuits 17, 18_1a, 18_1b, 18_2a, and 18_2b, an input terminal (or an input port) LNAin, and output terminals (or output ports) OUT1, OUT2. The operation of each circuit will be described later.

A coupling relationship of circuit elements in the high-frequency amplifier circuit 1 according to the embodiment will be described. The input terminal LNAin is coupled to a gate of an n-type MOS field-effect transistor FET11 via a capacitor Cx. A high-frequency input signal RFin is input to the input terminal LNAin via an external inductor Lext. A bias voltage VB1 is supplied to the gate of the transistor FET11 via a resistance RB1 from the bias-voltage generating circuit 14. A source of the transistor FET11 is coupled to a ground potential terminal (or a reference voltage terminal) GND via an inductor Ls1. A ground potential (or a reference voltage) of, for example, 0 V is supplied to the ground potential terminal GND.

A drain of the transistor FET11 is coupled to a source of an n-type MOS field-effect transistor FET21. A bias voltage VB2 is supplied to a gate of the transistor FET21 via a resistance RB21 from the bias-voltage generating circuit 14. A node between the gate of the transistor FET21 and the resistance RB21 is coupled to the ground potential terminal GND via a capacitor CB21.

A drain of the transistor FET21 is coupled to a power-supply voltage terminal VDD_LNA via an inductor Ld1. A power-supply voltage (e.g., 1.8 V) is supplied to the power-supply voltage terminal VDD_LNA.

The drain of the transistor FET21 is coupled to an output terminal OUT1 via a capacitor Cout1 and a switch T_Sw1. The capacitor Cout1 and the switch T_Sw1 are coupled in series between the drain of the transistor FET21 and the output terminal OUT1. The drain of the transistor FET21 is coupled to the switch T_Sw1 via a capacitor Cadd1 and a switch Sw2. The capacitor Cadd1 and the switch Sw2 are coupled in series between the drain of the transistor FET21 and the switch T_Sw1. That is, the capacitor Cout1 and the capacitor Cadd1 and the switch Sw2 are coupled in parallel between the drain of the transistor FET21 and the switch T_Sw1.

Moreover, the drain of the transistor FET21 is coupled to the ground potential terminal GND via a capacitor Cd1 and a switch Sw1.

A gate of an n-type MOS field-effect transistor FET12 is coupled to an electrode of the capacitor Cx. The bias voltage VB1 is supplied to the gate of the transistor FET12 via the resistance RB1 from the bias-voltage generating circuit 14. A source of the transistor FET12 is coupled to the ground potential terminal GND via an inductor Ls2.

A drain of the transistor FET12 is coupled to a source of an n-type MOS field-effect transistor FET22. The bias voltage VB2 is supplied to the gate of the transistor FET22 via a resistance RB22 from the bias-voltage generating circuit 14. A node between the gate of the transistor FET22 and the resistance RB22 is coupled to the ground potential terminal GND via a capacitor CB22.

A drain of the transistor FET22 is coupled to the power-supply voltage terminal VDD_LNA via an inductor Ld2.

The drain of the transistor FET22 is coupled to an output terminal OUT2 via a capacitor Cout2 and a switch T_Sw2. The capacitor Cout2 and the switch T_Sw2 are coupled in series between the drain of the transistor FET22 and the output terminal OUT2. The drain of the transistor FET22 is coupled to the switch T_Sw2 via a capacitor Cadd2 and a switch Sw4. The capacitor Cadd2 and the switch Sw4 are coupled in series between the drain of the transistor FET22 and the switch T_Sw2. That is, the capacitor Cout2 and the capacitor Cadd2 and the switch Sw4 are coupled in parallel between the drain of the transistor FET22 and the switch T_Sw2.

Moreover, the drain of the transistor FET22 is coupled to the ground potential terminal GND via a capacitor Cd2 and a switch Sw3.

A capacitor Csx is coupled between the source of the transistor FET11 and the source of the transistor FET12. A capacitor Cdx and a resistance Rdx are coupled between the drain of the transistor FET21 and the drain of the transistor FET22. The capacitor Cdx and the resistance Rdx are coupled in series between the drain of the transistor FET21 and the drain of the transistor FET22.

A switch T_Sw3 is coupled between a node ND1 between the capacitor Cout1 and the switch T_Sw1 and a node ND2 between the capacitor Cout2 and the switch T_Sw2.

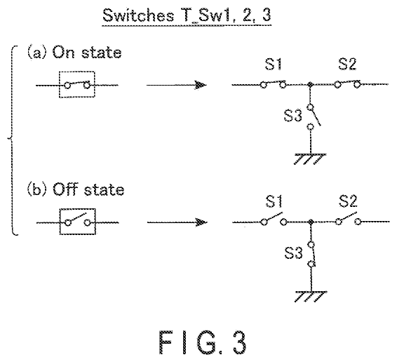

Each of the switches T_Sw1 to T_Sw3 is set to either an on state or an off state. FIG. 3 is a circuit diagram showing on/off states of each of the switches T_Sw1 to T_Sw3. Each of the switches T_Sw1 to T_Sw3 includes switching elements S1, S2, and S3. The switching elements S1 and S2 are coupled in series. The switching element S3 is coupled between a node between the switching element S1 and the switching element S2 and a ground potential terminal GND. Each of the switching elements S1 to S3 includes, for example, an n-type MOS field-effect transistor or a p-type MOS field-effect transistor.

The on state is a state in which the switching elements S1 and S2 are closed and the switching element S3 is open, as shown in FIG. 3(a). In the on state, one end and the other end of each of the switches T_Sw1 to T_Sw3 are coupled.

The off state is a state in which the switching elements S1 and S2 are open and the switching element S3 is closed, as shown in FIG. 3(b). In the off state, one end and the other end of each of the switches T_Sw1 to T_Sw3 are interrupted (or uncoupled).

Herein, an example is shown in which the transistors FET11, FET21, FET12, and FET22 are configured of n-type MOS field-effect transistors; however, they may be configured of p-type MOS field-effect transistors. For better electric characteristics, the transistors FET11, FET21, FET12, and FET22 should be configured of n-type MOS field-effect transistors, rather than p-type MOS field-effect transistors.

The circuit configuration of the above-described embodiment is not limited to the configuration shown in FIG. 2. Other configurations may be adopted as long as similar operations to those of the above-described embodiment can be realized.

1. 2 Operation of High-Frequency Amplifier Circuit 1

Hereinafter, an operation of the high-frequency amplifier circuit 1 according to the embodiment will be described. First, a basic operation of the high-frequency amplifier circuit 1 will be described, and a principal operation of the improving circuit of the high-frequency amplifier circuit 1 will be described.

Operation modes of the high-frequency amplifier circuit 1 include a single output mode which outputs a signal from one of the output terminals OUT1 and OUT2, and a split output mode which outputs signals from both of the output terminals OUT1 and OUT2. The single output mode is a mode that amplifies an input signal RFin input from the input terminal LNAin and outputs the amplified output signal RFout1 from the output terminal OUT1, or outputs the amplified output signal RFout2 from the output terminal OUT2. The split output mode is a mode that amplifies the input signal RFin input from the input terminal LNAin, and outputs the amplified output signals RFout1 and RFout2 from the output terminals OUT1 and OUT2, respectively. Hereinafter, the input terminal LNAin, the output terminal OUT1, and the output terminal OUT2 are also referred to as “port 1”, “port 2”, and “port 3”, respectively. The transmission characteristics and reflection characteristics are specified by the port numbers.

The amplifier circuit 11_1 includes a source-grounded transistor FET11 and a gate-grounded transistor FET21. The transistor FET11 and the transistor FET21 are cascade-coupled. That is, the drain of the transistor FET11 is coupled to the source of the transistor FET21.

The bias voltage VB1 is supplied to the gate of the transistor FET11 via the resistance RB1. Since the source of the transistor FET11 is coupled to the ground potential terminal GND via the inductor Ls1, the transistor FET11 functions as a source-grounded amplifier.

The bias voltage VB2 is supplied to the gate of the transistor FET21 via the resistance RB21. The gate of the transistor FET21 is coupled to the ground potential terminal GND via the capacitor CB21. That is, the gate of the transistor FET21 is coupled to the ground potential terminal GND in an alternating-current manner, and is grounded in the alternating-current manner. Since both the capacitance of the capacitor CB21 and the resistance value of the resistance RB21 are sufficiently large, the transistor FET21 functions as a gate-grounded amplifier.

The transistor FET11 amplifies the input signal RFin input to the input terminal LNAin. The transistor FET21 further amplifies the signal amplified by the transistor FET11, and generates an output signal RFout1.

The amplifier circuit 11_2 includes a source-grounded transistor FET12 and a gate-grounded transistor FET22. The transistor FET12 and the transistor FET22 are cascade-coupled. That is, the drain of the transistor FET12 is coupled to the source of the transistor FET22. The amplifier circuit 11_2 has the same circuit constant as the amplifier circuit 11_1. In other words, the amplifier circuit 11_1 has a first circuit constant, and the amplifier circuit 11_2 also has the same first circuit constant.

The bias voltage VB1 is supplied to the gate of the transistor FET12 via the resistance RB1. Since the source of the transistor FET12 is coupled to the ground potential terminal GND via the inductor Ls2, the transistor FET12 functions as a source-grounded amplifier.

The bias voltage VB2 is supplied to the gate of the transistor FET22 via the resistance RB22. The gate of the transistor FET22 is coupled to the ground potential terminal GND via the capacitor CB22. That is, the gate of the transistor FET22 is coupled to the ground potential terminal GND in an alternating-current manner, and is grounded in the alternating-current manner. Since the capacitance of the capacitor CB22 and the resistance value of the resistance RB22 are sufficiently large, the transistor FET22 functions as a gate-grounded amplifier.

The transistor FET12 amplifies the input signal RFin input to the input terminal LNAin. The transistor FET22 further amplifies the signal amplified by the transistor FET12, and generates an output signal RFout2.

The input matching circuit 12 includes the inductors Ls1, Ls2 and Lext, the capacitor Cx, and the input terminal LNAin. In the input matching circuit 12, the circuit constants of the inductors Ls1, Ls2 and Lext, and the capacitor Cx are configured in such a manner that the input impedance is set to approximately 50 ohms.

The inductors Ls1 and Ls2 have a function of ensuring consistency between a gain and a noise figure (NF) of the high-frequency amplifier circuit 1. By adjusting the inductances of the inductors Ls1 and Ls2, the gain and the noise figure NF can be set to an appropriate value. The inductance of each of the inductors Ls1 and Ls2 is, for example, 0.5 nH. The noise figure NF is defined as a ratio of a signal-to-noise (S/N) ratio of the input signal RFin to an S/N ratio of the output signal RFout1 or RFout2.

The inductor Lext is provided outside the high-frequency amplifier circuit 1. That is, the inductor Lext is, for example, not provided on the SOI substrate, and is externally attached by a discrete component, etc. Also, the capacitor Cx has a function of cutting off direct-current components of the input signal RFin.

The output matching circuit 13 includes the inductors Ld1 and Ld2, the capacitors Cout1, Cout2, Cadd1, Cadd2, Cd1, and Cd2, and the switches Sw1, Sw2, Sw3, and Sw4. In the output matching circuit 13, the circuit constants of the inductors Ld1 and Ld2 and the capacitors Cout1, Cout2, Cadd1, Cadd2, Cd1, and Cd2 are configured in such a manner that the output impedance is set to approximately 50 ohms. An unillustrated resistance for adjusting and stabilizing the gain may be coupled between the drain of the transistor FET21 and the power-supply voltage terminal VDD_LNA, and between the drain of the transistor FET22 and the power-supply voltage terminal VDD_LNA.

The bias-voltage generating circuit 14 generates the bias voltage VB1 to be supplied to the transistors FET11 and FET12 and the bias voltage VB2 to be supplied to the transistors FET21 and FET22. The resistances RB1, RB21 and RB22 are provided to prevent the input signal RFin from detouring around the bias-voltage generating circuit 14. The bias voltage VB1 is, for example, 0.5 V, and the bias voltage VB2 is, for example, 1.2 V.

The output switch circuit 15 includes the switches T_Sw1, T_Sw2, and T_Sw3. The output switch circuit 15 is provided to switch between the single output mode and the split output mode.

The switches T_Sw1 to T_Sw3 are switched between an on state and an off state by a control circuit (not illustrated) that controls the on/off states of the switches T_Sw1 to T_Sw3. When the switch T_Sw1 is set to the on state, one end and the other end of the switch T_Sw1 are brought to a coupled state. When the switch T_Sw1 is set to the off state, one end and the other end of the switch T_Sw1 are brought to an interrupted state (or an uncoupled state). Similarly, when the switch T_Sw2 is set to the on state, one end and the other end of the switch T_Sw2 are brought to a coupled state, and when the switch T_Sw2 is set to the off state, one end and the other end of the switch T_Sw2 are brought to an interrupted state. When the switch T_Sw3 is set to the on state, one end and the other end of the switch T_Sw3 are brought to a coupled state, and when the switch T_Sw3 is set to the off state, one end and the other end of the switch T_Sw3 are brought to an interrupted state.

By controlling the on/off states of the switches T_Sw1 to T_Sw3, the operation mode in the high-frequency amplifier circuit 1 is switched between the single output mode and the split output mode. The output switch circuit 15 will be described later.

The noise reduction circuit 16 includes the capacitor Csx coupled between the source of the transistor FET11 and the source of the transistor FET12. In the split output mode, the noise reduction circuit 16 reduces noise that detours around the gate of the transistor FET11 from the gate of the transistor FET12. Similarly, in the split output mode, the noise reduction circuit 16 reduces noise that detours around the gate of the transistor FET12 from the gate of the transistor FET11. The noise reduction circuit 16 reduces the noise level of the output signal in the split output mode to the noise level of the output signal in the single output mode. The noise reduction circuit 16 will be described later.

The output isolation improving circuit 17 includes the capacitor Cdx and the resistance Rdx. The capacitor Cdx and the resistance Rdx are coupled in series between the drain of the transistor FET21 and the drain of the transistor FET22. In the split output mode, the output isolation improving circuit 17 attenuates a signal that enters from the output terminal OUT2 (port 3), passes through the transistors FET22, FET12, FET11, and FET21, and is output from the output terminal OUT1 (port 2). That is, the output isolation improving circuit 17 is capable of improving scattering parameters (S-parameters) S23 indicating isolation between the output terminals OUT1 and OUT2. Similarly, in the split output mode, the output isolation improving circuit 17 attenuates a signal that enters from the output terminal OUT1 (port 2), passes through the transistors FET21, FET11, FET12, and FET22, and is output from the output terminal OUT2 (port 3). That is, the output isolation improving circuit 17 is capable of improving S-parameters S32 indicating isolation between the output terminals OUT1 and OUT2. The output isolation improving circuit 17 will be described later. The S-parameters will be described in detail in regard to the advantageous effects.

The output isolation improving circuits 18_1a, 18_1b, 18_2a, and 18_2b respectively correspond to the inductors Ls1, Ld1, Ls2, and Ld2. By adjusting a magnetic coupling coefficient between the inductor Ls1 and the inductor Ld1, and adjusting a magnetic coupling coefficient between the inductor Ls2 and the inductor Ld2, in the split output mode, a signal that enters from the output terminal OUT2 (or OUT1) and is output from the output terminal OUT1 (or OUT2) is attenuated. That is, the output isolation improving circuits 18_1a to 18_2b are capable of improving S-parameters S23 and S32 indicating isolation between the output terminals OUT1 and OUT2. The output isolation improving circuits 18_1a to 18_2b will be described later.

Hereinafter, operations of the output switch circuit 15, the noise reduction circuit 16, and the output isolation improving circuits 17, 18_1a, 18_1b, 18_2a, and 18_2b will be described.

1. 2. 1 Output Switch Circuit 15

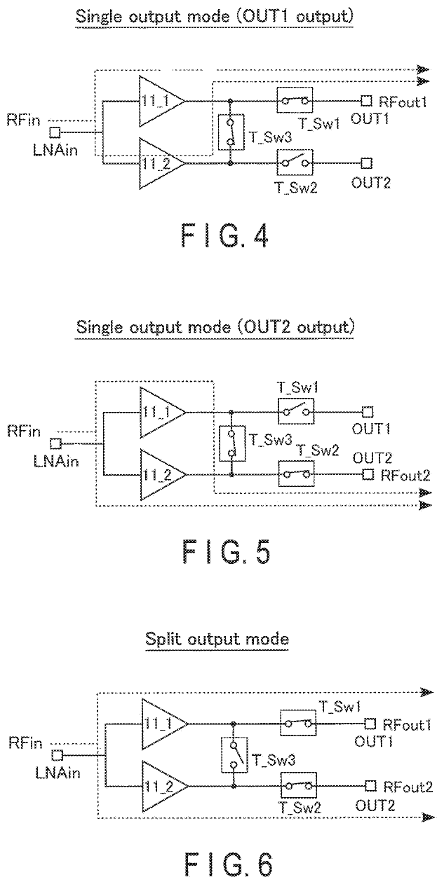

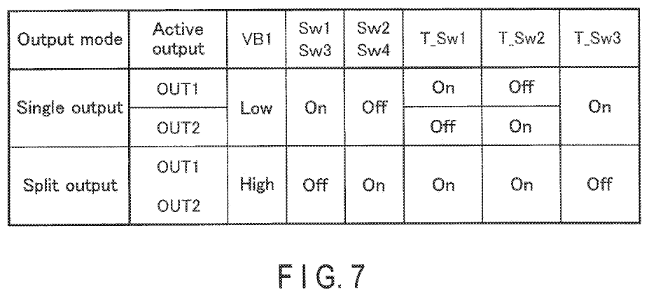

FIGS. 4, 5 and 6 are schematic diagrams showing the output switch circuit 15 in the high-frequency amplifier circuit 1 according to the embodiment. FIG. 7 shows a state of each switch in the single output mode and the split output mode. In the single output mode, the output terminal OUT1 or OUT2 is set to an active output, and in the split output mode, both the output terminals OUT1 and OUT2 are set to active outputs. An active output denotes which output terminal is valid.

In the single output mode, when the output terminal OUT1 is set to the active output, namely, when a signal is output from the output terminal OUT1, the operation is as follows. FIG. 4 shows the states of the switches when a signal is output from the output terminal OUT1 in the single output mode.

As shown in FIGS. 4 and 7, in the single output mode, when a signal is output from the output terminal OUT1, the bias voltage VB1 is set to a predetermined low voltage, and the switches T_Sw1 and T_Sw3 are set to the on state, and the switch T_Sw2 is set to the off state. Also, the switches Sw1 and Sw3 are set to the on state, and the switches Sw2 and Sw4 are set to the off state.

Thereby, the input signal RFin input to the input terminal LNAin is amplified by the amplifier circuit 11_1, and is output from the output terminal OUT1 via the switch T_Sw1. Also, the input signal RFin input to the input terminal LNAin and amplified by the amplifier circuit 11_2 is output from the output terminal OUT1 via the switches T_Sw3 and T_Sw1.

In the single output mode, when the output terminal OUT2 is set to the active output, namely, when a signal is output from the output terminal OUT2, the operation is as follows. FIG. 5 shows the states of the switches when a signal is output from the output terminal OUT2 in the single output mode.

As shown in FIGS. 5 and 7, in the single output mode, when a signal is output from the output terminal OUT2, the bias voltage VB1 is set to a predetermined low voltage, the switches T_Sw2 and T_Sw3 are set to the on state, and the switch T_Sw1 is set to the off state. Also, the switches Sw1 and Sw3 are set to the on state, and the switches Sw2 and Sw4 are set to the off state.

Thereby, the input signal RFin input to the input terminal LNAin is amplified by the amplifier circuit 11_2, and is output from the output terminal OUT2 via the switch T_Sw2. Also, the input signal RFin input to the input terminal LNAin and amplified by the amplifier circuit 11_1 is output from the output terminal OUT2 via the switches T_Sw3 and T_Sw2.

In the split output mode, when the output terminals OUT1 and OUT2 are set to the active outputs, namely, when a signal is output from each of the output terminals OUT1 and OUT2, the operation is as follows. FIG. 6 shows the states of the switches when a signal is output from each of the output terminals OUT1 and OUT2 in the split output mode.

As shown in FIGS. 6 and 7, in the split output mode, when a signal is output from each of the output terminals OUT1 and OUT2, the bias voltage VB1 is set to a predetermined high voltage, the switches T_Sw1 and T_Sw2 are set to the on state, and the switch T_Sw3 is set to the off state. Also, the switches Sw1 and Sw3 are set to the off state, and the switches Sw2 and Sw4 are set to the on state.

Thereby, the input signal RFin input to the input terminal LNAin is amplified by the amplifier circuit 11_1, and is output from the output terminal OUT1 via the switch T_Sw1. Also, the input signal RFin input to the input terminal LNAin and amplified by the amplifier circuit 11_2 is output from the output terminal OUT2 via the switch T_Sw2.

As described above, in the single output mode in which the output terminal OUT1 or OUT2 is set to the active output, the signal amplified by the amplifier circuit 11_1 or 11_2 is output from the output terminal OUT1 or OUT2. On the other hand, in the split output mode, the signals amplified by the amplifier circuits 11_1 and 11_2 are output from the output terminals OUT1 and OUT2, respectively.

In this manner, both of the amplifier circuits 11_1 and 11_2 operate in either the single output mode or the split output mode. That is, the signals amplified by the amplifier circuits 11_1 and 11_2 in either the single output mode or the split output mode are output from the output terminal without being interrupted. Thus, in either the single output mode or the split output mode, the impedance as viewed from the input side does not vary greatly.

The reason why the impedance does not vary greatly is that the value of the bias voltage VB1 differs between the single output mode and the split output mode, causing a slight change in the input impedance.

Thereby, a change in the input impedance in the single output mode and the split output mode can be reduced. Accordingly, the S-parameters S11 indicating reflection characteristics of the input side can be set to a favorable value in either the single output mode or the split output mode.

1. 2. 2 Noise Reduction Circuit 16

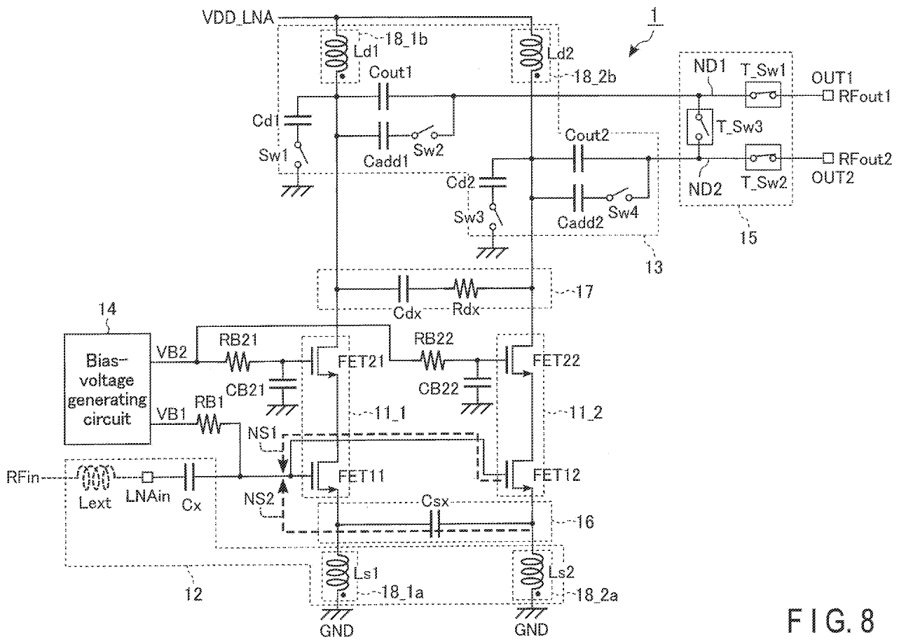

FIG. 8 is a diagram showing an operation of the noise reduction circuit 16 in the high-frequency amplifier circuit 1 according to the embodiment. In the split output mode, a noise NS1 that detours around the gate of the transistor FET11 from the gate of the transistor FET12 may be generated. The noise NS1 detours around the gate of the transistor FET11 from the gate of the transistor FET12 via an interconnect that couples the gate of the transistor FET12 and the gate of the transistor FET11.

The noise reduction circuit 16 in the high-frequency amplifier circuit 1 includes the capacitor Csx coupled between the source of the transistor FET11 and the source of the transistor FET12. Thereby, a noise NS2 that detours around the source and gate of the transistor FET11 from the source of the transistor FET12 via the capacitor Csx is generated.

Here, the circuit constants of the capacitor Csx and the inductors Ls1 and Ls2 are adjusted in such a manner that the noise NS2 has a 180-degree inverted phase with respect to the phase of the noise NS1. Thereby, the noise NS2 functions to cancel the noise NS1 out. That is, since the noise NS1 and the noise NS2 have 180-degree inverted phases, they cancel each other out, and the noise NS1 that detours around the gate of the transistor FET11 from the gate of the transistor FET12 is attenuated. Thereby, the noise figure NF in the high-frequency amplifier circuit 1 is not deteriorated in the split output mode.

Similarly, when a noise that detours around the gate of the transistor FET12 from the gate of the transistor FET11 is generated, the noise applied to the gate of the transistor FET12 by the noise reduction circuit 16 can be attenuated.

1. 2. 3 Output Isolation Improving Circuit 17

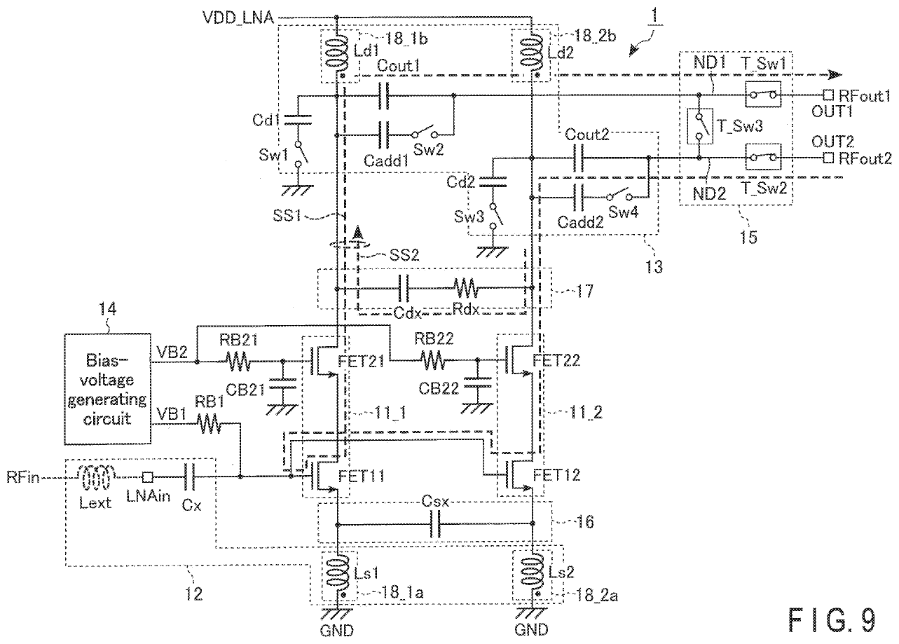

FIG. 9 is a diagram showing an operation of the output isolation improving circuit 17 in the high-frequency amplifier circuit 1 according to the embodiment. In the split output mode, a signal SS1 that enters from the output terminal OUT2 (port 3), passes through the transistors FET22, FET12, FET11, and FET21, and is output from the output terminal OUT1 (port 2) is generated.

The output isolation improving circuit 17 in the high-frequency amplifier circuit 1 includes the capacitor Cdx and the resistance Rdx that are coupled in series between the drain of the transistor FET21 and the drain of the transistor FET22. Thereby, the signal that enters from the output terminal OUT2 (port 3) is transmitted to the transistor FET22, and is also transmitted to the capacitor Cdx and the resistance Rdx. Thus, a signal SS2 that enters from the output terminal OUT2 (port 3), passes through the capacitor Cdx and the resistance Rdx, and is transmitted to a node at which the drain of the transistor FET21 and the capacitor Cdx are coupled is generated.

Here, the circuit constants of the capacitor Cdx and the resistance Rdx are adjusted in such a manner that the signal SS2 that has passed through the capacitor Cdx and the resistance Rdx has a 180-degree inverted phase with respect to the phase of the signal SS1. Thereby, the signal SS2 functions to cancel the signal SS1 out. That is, since the signal SS1 and the signal SS2 have 180-degree inverted phases, they cancel each other out, and attenuate the signal SS1 output from the output terminal OUT1. Thereby, in the split output mode, S-parameters S23 indicating isolation between the output terminals OUT1 and OUT2 can be improved.

Similarly, when a signal that enters from the output terminal OUT1 (port 2), passes through the transistor FET21, FET11, FET12, and FET22, and is output from the output terminal OUT2 (port 3) is generated, the output isolation improving circuit 17 is capable of attenuating a signal output from the output terminal OUT2.

1. 2. 4 Output Isolation Improving Circuits 18_1a, b and 18_2a, b

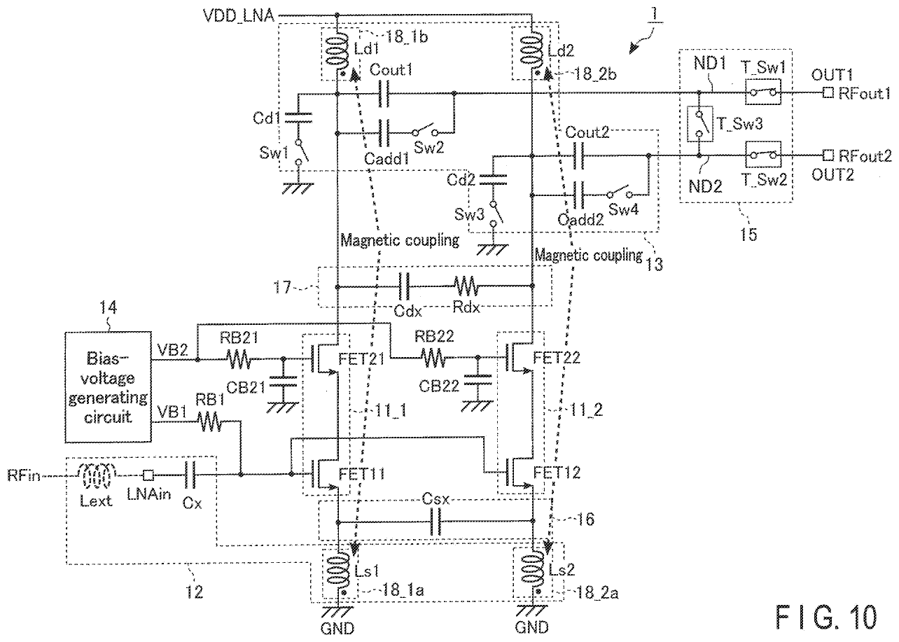

FIG. 10 is a diagram showing a relationship of magnetic coupling of the output isolation improving circuits 18_1a, 18_1b, 18_2a, and 18_2b in the high-frequency amplifier circuit 1 according to the embodiment. The output isolation improving circuits 18_1a to 18_2b are circuits that improve the S-parameters S23 (or S32) indicating isolation between the output terminals OUT1 and OUT2, similarly to the output isolation improving circuit 17.

In the output isolation improving circuits 18_1a to 18_2b in the high-frequency amplifier circuit 1, the inductor Ls1 and the inductor Ld1 are magnetically coupled with a magnetic coupling coefficient K. The polarity of the magnetic coupling between the inductor Ls1 and the inductor Ld1 is configured in such a manner that, when the polarity dot of the inductor Ls1 is put on the side of the ground potential terminal GND, the polarity dot of the inductor Ld1 is put on the side of the drain of the transistor FET21. It is assumed that the magnetic coupling coefficient K is, for example, 0.045.

Furthermore, the inductor Ls2 and the inductor Ld2 are magnetically coupled at the magnetic coupling coefficient K, similarly to the magnetic coupling between the inductor Ls1 and the inductor Ld1. The polarity of the magnetic coupling between the inductor Ls2 and the inductor Ld2 is configured in such a manner that, when the polarity dot of the inductor Ls2 is put on the side of the ground potential terminal GND, the polarity dot of the inductor Ld2 is put on the side of the drain of the transistor FET22. It is assumed that the magnetic coupling coefficient K is, for example, 0.045.

As described above, the magnetic coupling coefficient K between the inductor Ls1 and the inductor Ld1 is adjusted to be, for example, 0.045, and the magnetic coupling coefficient K between the inductor Ls2 and the inductor Ld2 is adjusted to be, for example, 0.045. Thereby, a signal that enters from the output terminal OUT2 (or OUT1) and is output to the output terminal OUT1 (or OUT2) can be attenuated. That is, the output isolation improving circuits 18_1a to 18_2b are capable of improving S-parameters S23 (or S32) indicating isolation between the output terminals OUT1 and OUT2 in the split output mode, similarly to the output isolation improving circuit 17.

1. 3. Circuit Layout

The inductors Ls1, Ld1, Ls2, and Ld2 included in the high-frequency amplifier circuit 1 according to the embodiment are, for example, spiral inductors provided on the SOI substrate. Specifically, they are the spiral inductors provided on a semiconductor layer on an insulating layer that configures the SOI substrate.

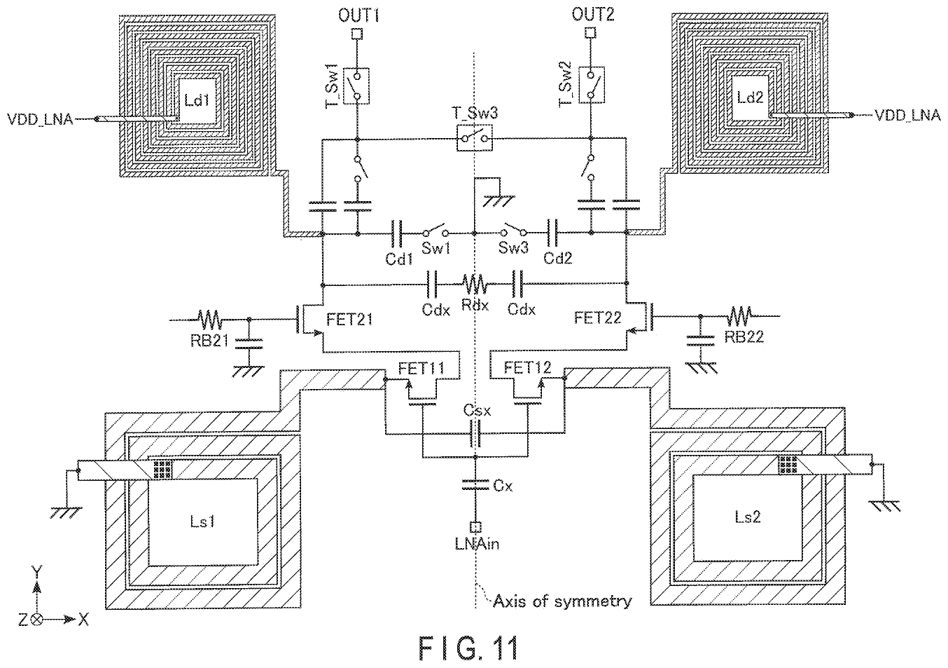

FIG. 11 is a schematic diagram of a layout of the high-frequency amplifier circuit 1 according to the embodiment. The inductors Ls1, Ld1, Ls2, and Ld2 are shown as a layout as viewed from above the SOI substrate. In other words, a state as viewed from above the semiconductor layer configuring the SOI substrate is shown.

In FIG. 11, the inductors Ls1, Ld1, Ls2, and Ld2 are shown in such a manner that their scales and relative positions approximately correspond to those of the layout on the SOI substrate. The principal circuit components excluding the inductors are shown as symbols at approximate positions on the SOI substrate.

Each of the inductors Ls1, Ld1, Ls2, and Ld2 is a conductive pattern (or an interconnect pattern) formed in a spiral (or helical) pattern on the semiconductor layer on the insulating layer. Each of the inductors Ls1, Ld1, Ls2, and Ld2 is formed in a rectangular spiral pattern.

Specifically, the inductor Ls1 is arranged in a spiral pattern going inward in a counterclockwise direction, as viewed from above the SOI substrate. One end of an outermost periphery of the inductor Ls1 is coupled to the source of the transistor FET11. Another end of an innermost periphery of the inductor Ls1 is coupled to the ground potential terminal GND. The inductor Ld1 is arranged in a spiral pattern going inward in a counterclockwise direction, as viewed from above the SOI substrate. One end of an outermost periphery of the inductor Ld1 is coupled to the drain of the transistor FET21. Another end of an innermost periphery of the inductor Ld1 is coupled to the power-supply voltage terminal VDD_LNA.

The inductor Ls2 is arranged in a spiral pattern going inward in a clockwise direction, as viewed from above the SOI substrate. One end of an outermost periphery of the inductor Ls2 is coupled to the source of the transistor FET12. Another end of an innermost periphery of the inductor Ls2 is coupled to the ground potential terminal GND. Furthermore, the inductor Ld2 is arranged in a spiral pattern going inward in a clockwise direction, as viewed from above the SOI substrate. One end of an outermost periphery of the inductor Ld2 is coupled to the drain of the transistor FET22. Another end of an innermost periphery of the inductor Ld2 is coupled to the power-supply voltage terminal VDD_LNA.

The layout shown in FIG. 11 is line-symmetric with respect to the Y-direction line (axis of symmetry) that goes through the center of the layout of the high-frequency amplifier circuit 1. That is, the inductors Ls1 and Ls2 are line-symmetrically arranged with respect to the axis of symmetry. Similarly, the inductors Ld1 and Ld2 are line-symmetrically arranged with respect to the axis of symmetry. The other circuit elements are arranged in an approximately line-symmetrical manner with respect to the axis of symmetry.

Thereby, a pair of cascade-coupled amplifier circuits, namely, amplifier circuits 11_1 and 11_2 perform the same amplification operation without causing a phase difference in signals to be amplified.

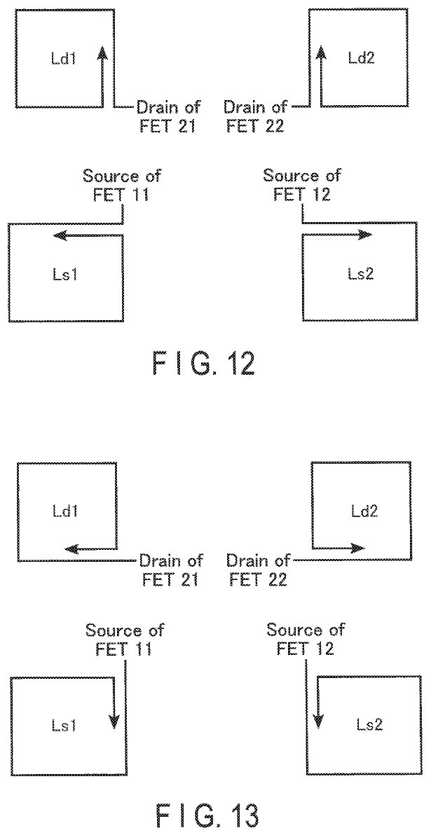

FIG. 12 is a schematic diagram showing winding directions of the inductors Ls1, Ld1, Ls2, and Ld2 in FIG. 11. The winding directions of the inductors Ls1 and Ld1 are the same, inward in the counterclockwise direction. The winding directions of the inductors Ls2 and Ld2 are the same, inward in the clockwise direction.

The polarity of the magnetic coupling between the inductors Ls1 and Ld1 shown in FIG. 12 corresponds to the polarity of the magnetic coupling between the inductors Ls1 and Ld1 shown in FIG. 2. Similarly, the polarity of the magnetic coupling between the inductors Ls2 and Ld2 corresponds to the polarity of the magnetic coupling between the inductors Ls2 and Ld2 shown in FIG. 2.

FIG. 13 is a schematic diagram showing another example of winding directions of the inductors Ls1, Ld1, Ls2, and Ld2. The winding directions of the inductors Ls1, Ld1, Ls2, and Ld2 shown in FIG. 13 are opposite to the winding directions shown in FIG. 12. That is, the winding directions of the inductors Ls1 and Ld1 are directions going inward in the clockwise direction. The winding directions of the inductors Ls2 and Ld2 are directions going inward in the counterclockwise direction.

The winding directions of the inductors Ls1 and Ld1 shown in FIG. 12 may be opposite, as shown in FIG. 13. Similarly, the winding directions of the inductors Ls2 and Ld2 shown in FIG. 12 may be opposite, as shown in FIG. 13. That is, it suffices that the polarity of the magnetic coupling between the inductors Ls1 and Ld1 and the polarity of the magnetic coupling between the inductors Ls2 and Ld2 is one of the polarities shown in FIGS. 2 and 3.

1. 4 Advantageous Effects

According to the present embodiment, it is possible to provide the high-frequency amplifier circuit that is excellent in isolation between the output ports in the split output mode.

Advantageous effects of the embodiment will be described below.

In the high-frequency amplifier circuit 1 according to the embodiment, S-parameters and a noise figure NF in the single output mode and the split output mode are calculated by simulation. In the embodiment, it is assumed that the high-frequency amplifier circuit 1 is used in Band41 (e.g., 2496 MHz to 2690 MHz). Also, it is assumed that the input matching circuit 12 is configured in such a manner that the inductor Lext is coupled to the input terminal LNAin, as shown in FIG. 2.

The S-parameters are parameters indicating transmission characteristics and reflection characteristics in high-frequency circuitry. It is assumed that the input terminal LNAin is port 1, the output terminal OUT1 is port 2, and the output terminal OUT2 is port 3. Using these port numbers, the S-parameters are indicated as “S21”, “S11”, “S22”, and “S23”. S21 indicates transmission characteristics from the input side to the output side, namely, transmission characteristics of the input signal RFin from the input terminal LNAin (port 1) to the output terminal OUT1 (port 2). S21 indicates a degree of amplification of the output signal RFout1 (or RFout2) with respect to the input signal RFin. S11 indicates reflection characteristics of the input side, namely, reflection characteristics of the input signal RFin input to the input terminal LNAin. S22 indicates reflection characteristics of the output side, namely, reflection characteristics of the signal that has entered from the output terminal OUT1. S23 indicates transmission characteristics from one output side (port 3) to another output side (port 2), namely, transmission characteristics from the output terminal OUT2 to the output terminal OUT1 of the signal that has entered the output terminal OUT2. S23 is also referred to as “isolation between output ports” (or “isolation between outputs”).

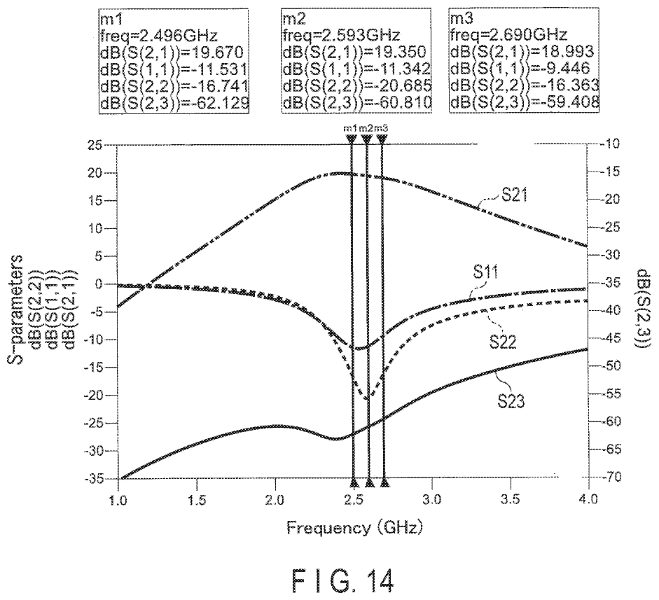

FIG. 14 shows S-parameters of the high-frequency amplifier circuit 1 in the single output mode according to the embodiment. The lateral axis of FIG. 14 indicates a frequency (GHz) of the input signal RFin, and the vertical axis indicates S-parameters (dB). In FIG. 14 and the drawings subsequent thereto, “m1”, “m2”, and “m3” at the upper part of the drawings showing the S-parameters respectively denote values of S-parameters at the frequencies 2496 MHz, 2593 MHz, and 2690 MHz.

At the central frequency 2593 MHz of the frequency band from 2496 MHz to 2690 MHz, S21 in the embodiment is 19.35 dB. S21 satisfies the value that is required by design.

S11 in the embodiment in the frequency band from 2496 MHz to 2690 MHz is equal to or lower than −9.4 dB. S11 satisfies the generally required value (e.g., equal to or lower than −8 dB). Also, in the frequency band from 2496 MHz to 2690 MHz, S22 in the embodiment is equal to or lower than −16.3 dB. S22 satisfies the generally required value (e.g., equal to or lower than −12 dB). Accordingly, the reflection characteristics denoted by S11 and S22 in the present embodiment are favorable.

In the frequency band from 2496 MHz to 2690 MHz, S23 in the embodiment is equal to or lower than −59.4 dB. S23 satisfies the generally required value (e.g., equal to or lower than −25 dB).

In the single output mode of the embodiment, the switch coupled to the output terminal that is not selected as the output side is set to the off state. For example, if the output terminal OUT1 is selected as a terminal to which a signal is output, the switch T_Sw2 coupled to the output terminal OUT2 is set to the off state. Conversely, if the output terminal OUT2 is selected as a terminal to which a signal is output, the switch T_Sw1 coupled to the output terminal OUT1 is set to the off state. Thereby, the S-parameters S23 indicating the isolation between the output ports can be improved.

Even though S31, S32, and S33 are not illustrated, since the circuit constants of the amplifier circuits 11_1 and 11_2, the input matching circuit 12, the output matching circuit 13, etc. are adjusted, the values of S31, S32, and S33 are approximately the same as the values of S21, S23, and S22.

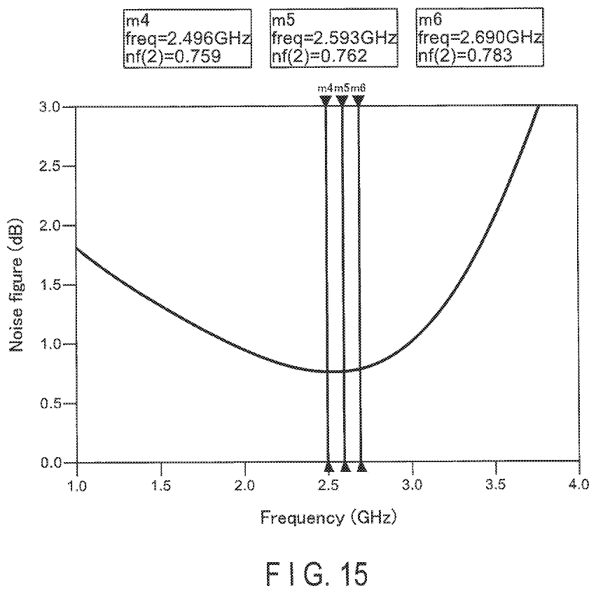

FIG. 15 shows a noise figure NF of the high-frequency amplifier circuit 1 in the single output mode, according to the embodiment. The lateral axis of FIG. 15 indicates a frequency (GHz) of the input signal RFin, and the vertical axis indicates a noise figure NF (dB). In FIG. 15 and the drawings subsequent thereto, “m4”, “m5”, and “m6” at the upper part of the drawings showing the noise figure NF respectively denote noise figures NF at the frequencies 2496 MHz, 2593 MHz, and 2690 MHz.

In the frequency band from 2496 MHz to 2690 MHz, the noise figure NF in the embodiment is equal to or lower than 0.78 dB. Accordingly, the noise figure NF in the embodiment is favorable.

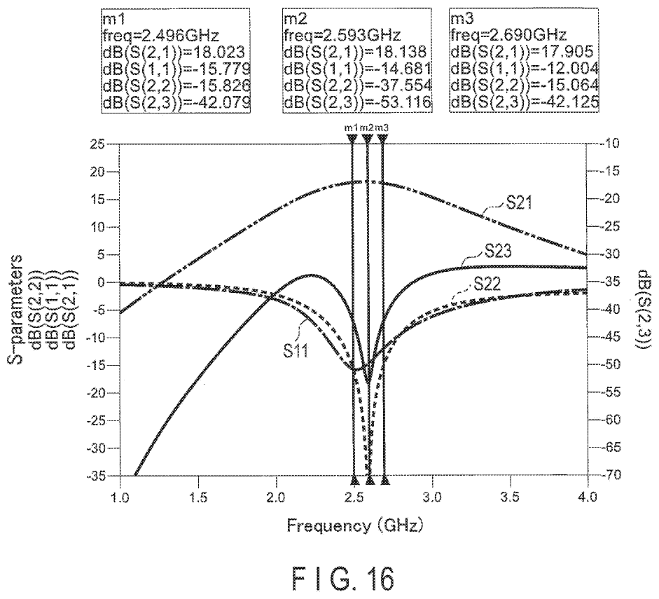

FIG. 16 shows S-parameters of the high-frequency amplifier circuit 1 in the split output mode according to the embodiment. The lateral axis indicates a frequency (GHz) of the input signal RFin, and the vertical axis indicates S-parameters (dB).

At the central frequency 2593 MHz of the frequency band from 2496 MHz to 2690 MHz, S21 in the embodiment is 18.1 dB. S21 satisfies the value that is required by design.

Also, S11 in the embodiment in the frequency band from 2496 MHz to 2690 MHz is equal to or below −12.0 dB. S11 satisfies the generally required value (e.g., equal to or lower than −8 dB). Also, in the frequency band from 2496 MHz to 2690 MHz, S22 in the embodiment is equal to or below −15.0 dB. S22 satisfies the generally required value (e.g., equal to or lower than −12 dB). Accordingly, the reflection characteristics denoted by S11 and S22 in the present embodiment are favorable.

In the frequency band from 2496 MHz to 2690 MHz, S23 in the embodiment is equal to or lower than −42.0 dB. S23 satisfies the generally required value (e.g., equal to or lower than −25 dB). The S-parameters S23 denoting the isolation between outputs will be evaluated in comparison to the comparison example to be described later.

Even though S31, S32, and S33 are not illustrated, since the circuit constants of the amplifier circuits 11_1 and 11_2, the input matching circuit 12, the output matching circuit 13, etc. are adjusted, the values of S31, S32, and S33 are approximately the same as the values of S21, S23, and S22.

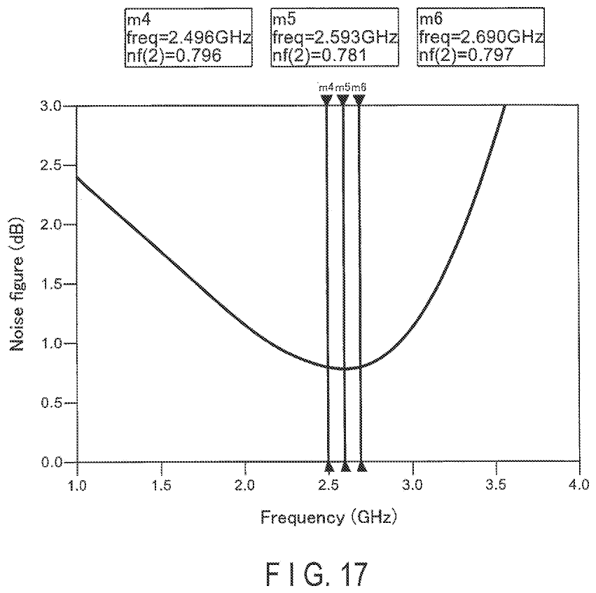

FIG. 17 shows a noise figure NF of the high-frequency amplifier circuit 1 in the split output mode, according to the embodiment. The lateral axis indicates a frequency (GHz) of the input signal RFin, and the vertical axis indicates a noise figure NF (dB).

In the frequency band from 2496 MHz to 2690 MHz, the noise figure NF in the embodiment is equal to or lower than 0.80 dB. Accordingly, the noise figure NF in the embodiment is favorable.

In the present embodiment, as described above, the polarity of the magnetic coupling between the inductor Ls1 and the inductor Ld1 is configured in such a manner that, when the polarity dot of the inductor Ls1 is put on the side of the ground potential terminal GND, the polarity dot of the inductor Ld1 is put on the side of the drain of the transistor FET21. Also, when the polarity dot of the inductor Ls2 is put on the side of the ground potential terminal GND, the polarity dot of the inductor Ld2 is put on the drain side of the transistor FET22.

To explain an advantageous effect of the case where the polarity of the magnetic coupling coefficient K of the inductors is set as described above in the embodiment, the characteristics of a comparative example in which the polarity of the magnetic coupling coefficient is opposite to that of the embodiment will be described below.

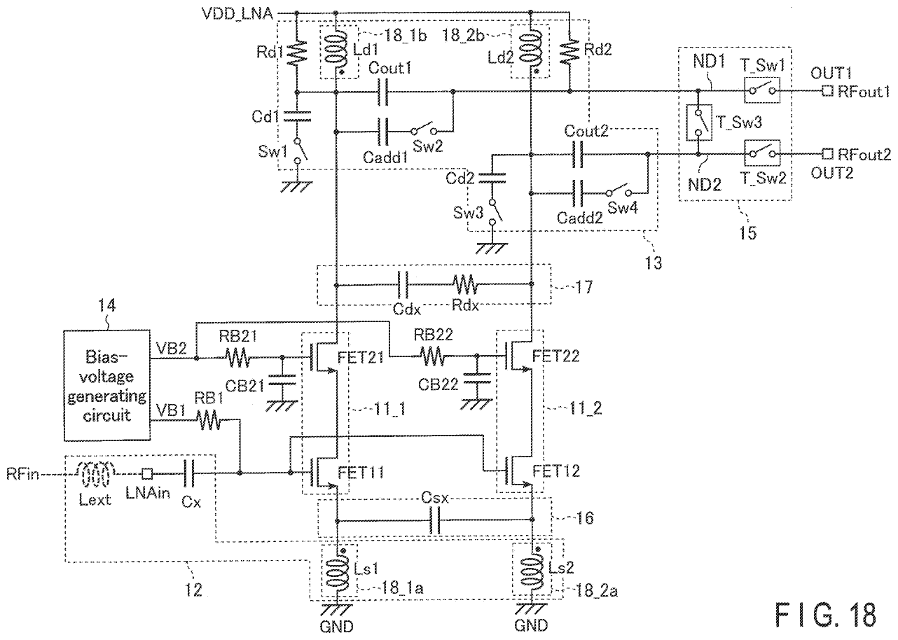

FIG. 18 is a circuit diagram showing a configuration of a high-frequency amplifier circuit according to the comparative example. In the comparative example, the polarity of the magnetic coupling between the inductors Ls1 and Ld1 and the polarity of the magnetic coupling between the inductors Ls2 and Ld2 are opposite to those of the circuit configuration shown in FIG. 2.

That is, in the comparative example, the polarity of the magnetic coupling between the inductors Ls1 and Ld1 is configured in such a manner that, when the polarity dot of the inductor Ls1 is put on the source side of the transistor FET11, the polarity dot of the inductor Ld1 is put on the drain side of the transistor FET21. Also, when the polarity dot of the inductor Ls2 is put on the source side of the transistor FET12, the polarity dot of the inductor Ld2 is put on the drain side of the transistor FET22.

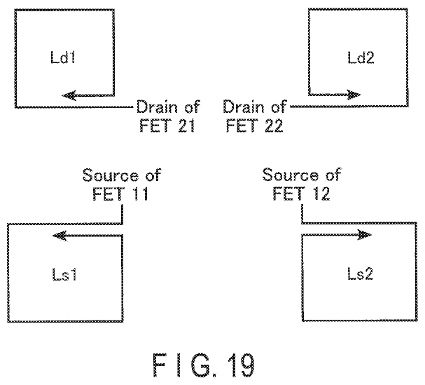

FIG. 19 schematically shows winding directions of the inductors Ls1, Ld1, Ls2, and Ld2 in FIG. 18. The winding direction of the inductor Ls1 is a direction going inward in the counterclockwise direction. The winding direction of the inductor Ld1 is a direction opposite to the winding direction of the inductor Ls1, and is a direction going inward in a clockwise direction. The winding direction of the inductor Ls2 is a direction going inward in a clockwise direction. The winding direction of the inductor Ld2 is opposite to the winding direction of the inductor Ls2, and is a direction going inward in a counterclockwise direction.

In the comparative example, the magnetic coupling coefficient K between the inductors Ls1 and Ld1, and the magnetic coupling coefficient K between the inductor Ls2 and Ld2 are set to have the same value (e.g., 0.045) as that of the embodiment, even though the polarities are opposite to those of the embodiment.

The other circuit configuration in the comparative example is similar to the circuit configuration shown in FIG. 2, except for the resistances Rd1 and Rd2. The resistances Rd1 and Rd2 are added to make the gain in the central frequency of the frequency band in the split output mode the same as that of the embodiment.

In the comparative example, S-parameters in the single output mode and the split output mode are calculated by simulation. In the comparative example, too, usage in Band41 (2496 MHz to 2690 MHz) is assumed. Also, it is assumed that the input matching circuit 12 is configured in such a manner that the inductor Lext is coupled to the input terminal LNAin, as shown in FIG. 18.

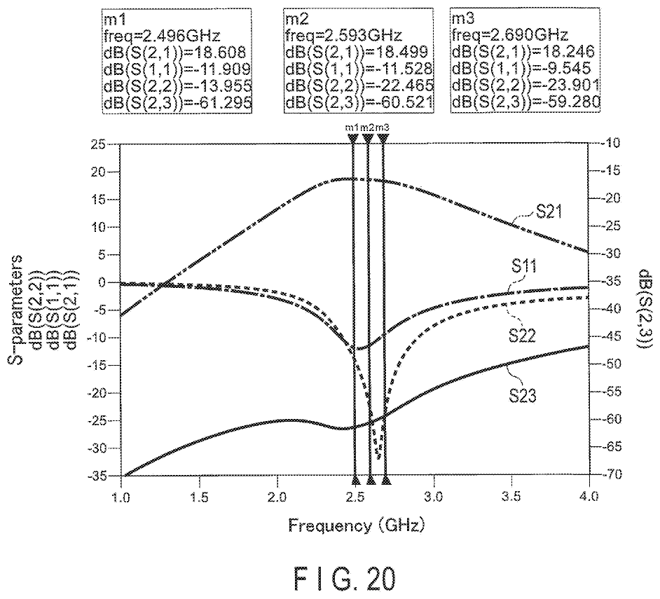

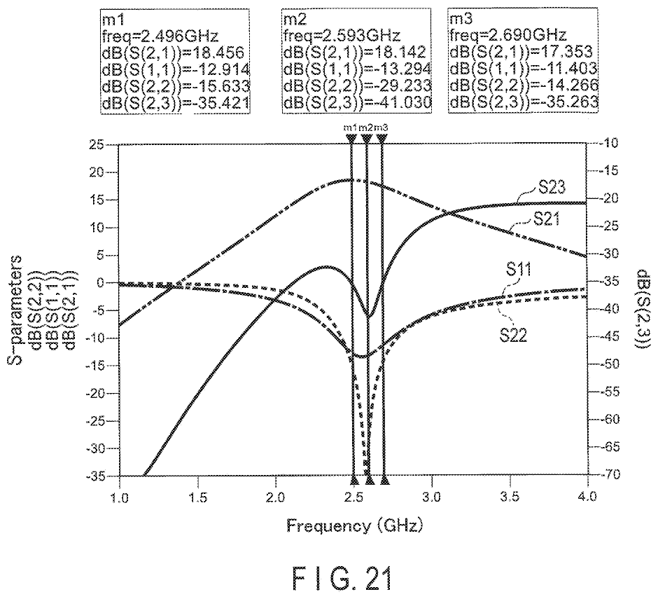

FIG. 20 shows S-parameters in the single output mode according to the comparative example. FIG. 21 shows S-parameters in the split output mode according to the comparative example.

The S-parameters S21, S11, S22, S23 in the single output mode of the comparative example have approximately the same values as those of the S-parameters of the embodiment. However, when attention is focused on the S-parameters S23 in the split output mode of the comparative example, S23 is equal to or lower than −35.4 dB in the frequency band from 2496 MHz to 2690 MHz. S23 is worse by approximately 6.6 dB than −42.0 dB in the embodiment. Accordingly, it can be seen that the S-parameters S23 denoting isolation between the output ports are sufficiently improved, compared to the comparative example. The other S-parameters in the split output mode of the comparative example have approximately the same values as those of the S-parameters of the embodiment.

Even though the S-parameters S32 are not illustrated, since the circuit constants of the amplifier circuits 11_1 and 11_2, the input matching circuit 12, and the output matching circuit 13 are adjusted, the value of S32 is approximately the same as the value of S23.

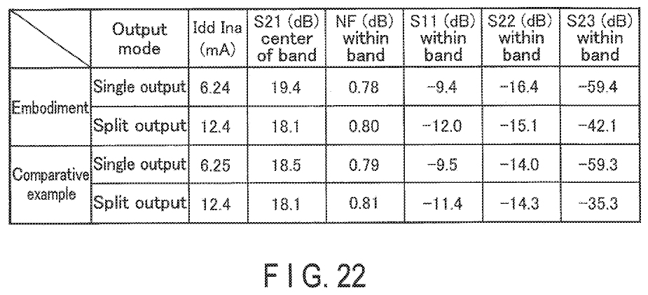

FIG. 22 shows values of various characteristics (S-parameters and noise figures NF) according to the embodiment and the comparative example. The various characteristics are calculated based on the conditions that the input signal RFin has a frequency band from 2496 MHz to 2690 MHz, and the power-supply voltage terminal VDD_LNA is 1.2 V. The bias current in the single output mode of the embodiment is 6.24 mA, and the bias current in the single output mode of the comparative example is 6.25 mA. The bias current in the split output mode is 12.4 mA in both the embodiment and the comparative example.

As is clear from FIG. 22, the embodiment is capable of improving the S-parameters S23 compared to the comparative example. Furthermore, the embodiment is capable of improving the S-parameters S22 compared to the comparative example.

### 2. Other Modifications, Etc.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A high frequency amplifier circuit comprising:
a first transistor including a gate to which an input signal is input;
a first inductor coupled between a source of the first transistor and a reference voltage terminal;
a second transistor including a gate that is grounded in an alternating-current manner, and a source coupled to a drain of the first transistor;
a second inductor coupled between a drain of the second transistor and a power-supply voltage terminal;
a first switch coupled between a first output terminal and a first node located between the drain of the second transistor and the second inductor;
a third transistor including a gate to which the input signal is input;
a third inductor coupled between a source of the third transistor and the reference voltage terminal;
a fourth transistor including a gate that is grounded in the alternating-current manner, and a source coupled to a drain of the third transistor;
a fourth inductor coupled between a drain of the fourth transistor and the power-supply voltage terminal;
a second switch coupled between a second output terminal and a second node located between the drain of the fourth transistor and the fourth inductor; and
a third switch coupled between the first node and the second node.

2. The high frequency amplifier circuit according to claim 1, wherein
the first inductor and the second inductor are magnetically coupled at a first magnetic coupling coefficient, and regarding a polarity of the magnetic coupling between the first inductor and the second inductor, when a polarity dot of the first inductor is put on a side of the reference voltage terminal, a polarity dot of the second inductor is put on a side of the drain of the second transistor, and
the third inductor and the fourth inductor are magnetically coupled at the first magnetic coupling coefficient, and regarding a polarity of the magnetic coupling between the third inductor and the fourth inductor, when a polarity dot of the third inductor is put on the side of the reference voltage terminal, a polarity dot of the fourth inductor is put on a side of the drain of the fourth transistor.

3. The high frequency amplifier circuit according to claim 1, wherein
the first inductor, the second inductor, the third inductor, and the fourth inductor are provided on a substrate,
the first inductor is arranged in a spiral pattern going inward in a first rotation direction as viewed from above the substrate, a first end of an outer periphery of the first inductor being coupled to the source of the first transistor and a second end of an inner periphery of the first inductor being coupled to the reference voltage terminal,
the second inductor is arranged in a spiral pattern going inward in the first rotation direction as viewed from above the substrate, a first end of an outer periphery of the second inductor being coupled to the drain of the second transistor and a second end of an inner periphery of the second inductor being coupled to the power-supply voltage terminal,
the third inductor is arranged in a spiral pattern going inward in a second rotation direction as viewed from above the substrate, a first end of an outer periphery of the third inductor being coupled to the source of the third transistor and a second end of an inner periphery of the third inductor being coupled to the reference voltage terminal, and
the fourth inductor is arranged in a spiral pattern going inward in the second rotation direction as viewed from above the substrate, a first end of an outer periphery of the fourth inductor being coupled to the drain of the fourth transistor and a second end of an inner periphery of the fourth inductor being coupled to the power-supply voltage terminal.

4. The high frequency amplifier circuit according to claim 3, wherein the first rotation direction is a counterclockwise direction, and the second rotation direction is a clockwise direction.

5. The high frequency amplifier circuit according to claim 3, wherein the first rotation direction is a clockwise direction, and the second rotation direction is a counterclockwise direction.

6. The high frequency amplifier circuit according to claim 1, wherein the first inductor, the second inductor, the third inductor, and the fourth inductor include conductive spiral patterns provided on a substrate.

7. The high frequency amplifier circuit according to claim 1, further comprising a capacitor coupled between the source of the first transistor and the source of the third transistor.

8. The high frequency amplifier circuit according to claim 1, further comprising a resistance and a capacitor coupled in series between the drain of the second transistor and the drain of the fourth transistor.

9. The high frequency amplifier circuit according to claim 1, comprising:
a first operation of setting the first switch to a coupled state, setting the second switch to an interrupted state, and setting the third switch to the coupled state;
a second operation of setting the first switch to the interrupted state, setting the second switch to the coupled state, and setting the third switch to the coupled state; and
a third operation of setting the first switch to the coupled state, setting the second switch to the coupled state, and setting the third switch to the interrupted state.

10. The high frequency amplifier circuit according to claim 1, wherein
the first transistor and the second transistor configure a first amplifier circuit that amplifies the input signal,
the third transistor and the fourth transistor configure a second amplifier circuit that amplifies the input signal, and
the first amplifier circuit and the second amplifier circuit have a first circuit constant.

11. The high frequency amplifier circuit according to claim 1, comprising:
a single output mode in which a first signal output from the second transistor and a second signal output from the fourth transistor are output from one of the first output terminal and the second output terminal; and
a split output mode in which the first signal is output from the first output terminal, and the second signal is output from the second output terminal.

12. The high frequency amplifier circuit according to claim 3, wherein the substrate includes a silicon-on-insulator (SOI) substrate.

13. The high frequency amplifier circuit according to claim 6, wherein the substrate includes a silicon-on-insulator (SOI) substrate.

14. A high frequency amplifier circuit comprising:
a first amplifier circuit including a first transistor and a second transistor, the first transistor including a source grounded via a first inductor and a gate to which an input signal is input, the second transistor including a source to which a signal output from a drain of the first transistor is input, a drain to which a power-supply voltage is supplied via a second inductor, and a grounded gate;
a first switch coupled between a first output terminal and a first node located between the drain of the second transistor and the second inductor;
a second amplifier circuit including a third transistor and a fourth transistor, the third transistor including a source grounded via a third inductor and a gate to which the input signal is input, the fourth transistor including a source to which a signal output from a drain of the third transistor is input, a drain to which the power-supply voltage is supplied via a fourth inductor, and a grounded gate;
a second switch coupled between a second output terminal and a second node located between the drain of the fourth transistor and the fourth inductor; and
a third switch coupled between the first node and the second node.

15. The high frequency amplifier circuit according to claim 14, wherein
the first inductor and the second inductor are magnetically coupled at a first magnetic coupling coefficient, and regarding a polarity of the magnetic coupling between the first inductor and the second inductor, when a polarity dot of the first inductor is put on a side of the reference voltage terminal, a polarity dot of the second inductor is put on a side of the drain of the second transistor, and
the third inductor and the fourth inductor are magnetically coupled at the first magnetic coupling coefficient, and regarding a polarity of the magnetic coupling between the third inductor and the fourth inductor, when a polarity dot of the third inductor is put on the side of the reference voltage terminal, a polarity dot of the fourth inductor is put on a side of the drain of the fourth transistor.

16. The high frequency amplifier circuit according to claim 14, wherein
the first inductor, the second inductor, the third inductor, and the fourth inductor are provided on a substrate,
the first inductor is arranged in a spiral pattern going inward in a first rotation direction as viewed from above the substrate, a first end of an outer periphery of the first inductor being coupled to the source of the first transistor and a second end of an inner periphery of the first inductor being coupled to the reference voltage terminal,
the second inductor is arranged in a spiral pattern going inward in the first rotation direction as viewed from above the substrate, with a first end of an outer periphery of the second inductor being coupled to the drain of the second transistor and a second end of an inner periphery of the second inductor being coupled to the power-supply voltage terminal,
the third inductor is arranged in a spiral pattern going inward in a second rotation direction as viewed from above the substrate, a first end of an outer periphery of the third inductor being coupled to the source of the third transistor and a second end of an inner periphery of the third inductor being coupled to the reference voltage terminal, and
the fourth inductor is arranged in a spiral pattern going inward in the second rotation direction as viewed from above the substrate, a first end of an outer periphery of the fourth inductor being coupled to the drain of the fourth transistor and a second end of an inner periphery of the fourth inductor being coupled to the power-supply voltage terminal.

17. The high frequency amplifier circuit according to claim 16, wherein the first direction is a counterclockwise direction, and the second direction is a clockwise direction.

18. The high frequency amplifier circuit according to claim 14, wherein the first inductor, the second inductor, the third inductor, and the fourth inductor include conductive spiral patterns provided on a substrate.

19. The high frequency amplifier circuit according to claim 14, further comprising a capacitor coupled between the source of the first transistor and the source of the third transistor.

20. The high frequency amplifier circuit according to claim 14, further comprising a resistance and a capacitor coupled in series between the drain of the second transistor and the drain of the fourth transistor.
